(19) United States
(12) Patent Application Publication
(10) Pub. No.: US 2023/0207370 A1
(43) Pub. Date: Jun. 29, 2023

(54) MEMBER FOR SEMICONDUCTOR MANUFACTURING APPARATUS

(71) Applicant: NGK Insulators, Ltd., Nagoya-City (JP)

(72) Inventors: Seiya INOUE, Handa-City (JP); Tatsuya KUNO, Nagoya-City (JP)

(73) Assignee: NGK Insulators, Ltd., Nagoya-City (JP)

(21) Appl. No.: 18/055,476

(22) Filed: Nov. 15, 2022

(30) Foreign Application Priority Data
Dec. 27, 2021 (JP) 2021-211864

(51) Int. Cl. H01L 21/683

(52) U.S. Cl. CPC H01L 21/6833

(57) ABSTRACT

A member for semiconductor manufacturing apparatus includes: a ceramic plate; a metal joining layer and a cooling plate (conductive substrate) provided at a lower surface of the ceramic plate; a first hole penetrating the ceramic plate in an up-down direction; and a through-hole and a gas hole (second hole) penetrating the conductive substrate in an up-down direction, and communicating with the first hole. A dense insulating case has a bottomed hole 64 opened in a lower surface, and is disposed in the first hole and the second hole. A plurality of microholes penetrates a bottom of the bottomed hole in an up-down direction. A porous plug is disposed in the bottomed hole and in contact with the bottom.

### BACKGROUND OF THE INVENTION

### 1. Field of the Invention

The present invention relates to a member for semiconductor manufacturing apparatus.

### 2. Description of the Related Art

In a known member for semiconductor manufacturing apparatus in the related art, an electrostatic chuck having a wafer placement surface is provided on a cooling device. For example, the member for semiconductor manufacturing apparatus in PTL 1 includes: a gas supply hole provided in a cooling device; a recess section provided in an electrostatic chuck so as to communicate with the gas supply hole; microholes penetrating from the bottom surface of the recess section to a wafer placement surface; and a porous plug composed of an insulating material filled in the recess section. When a back side gas such as helium is introduced into the gas supply hole, the gas is supplied to the space on the rear-surface side of the wafer through the gas supply hole, the porous plug and the microholes.

### CITATION LIST

### Patent Literature

PTL 1: JP 2013-232640 A

### SUMMARY OF THE INVENTION

However, in the above-mentioned member for semiconductor manufacturing apparatus, the bottom of the ceramic plate included in the electrostatic chuck is provided with microholes, thus, it has been difficult in machining to reduce the length of the microholes in an up-down direction.

The present invention has been devised to address such a problem, and it is a main object to improve machinability of microholes that allow the wafer placement surface and the upper surface of the porous plug to communicate with each other.

A member for semiconductor manufacturing apparatus of the present invention includes: a ceramic plate having a wafer placement surface on its upper surface; a conductive substrate provided at a lower surface of the ceramic plate; a first hole penetrating the ceramic plate in an up-down direction; a second hole penetrating the conductive substrate in an up-down direction, and communicating with the first hole; a dense insulating case that has a bottomed hole opened in a lower surface, and is disposed in the first hole and the second hole; a plurality of microholes penetrating a bottom of the bottomed hole in an up-down direction; and a porous plug disposed in the bottomed hole and in contact with the bottom.

In the member for semiconductor manufacturing apparatus, the bottom of a bottomed hole of an insulating case, which is a separate body from the ceramic plate, is provided with a plurality of microholes. Thus, the machinability of the microholes is improved, as compared to when the ceramic plate is directly provided with a plurality of microholes.

In the member for semiconductor manufacturing apparatus of the present invention, the wafer placement surface may have a large number of small projections that support a wafer, an upper surface of the insulating case may be at a same height as a reference surface of the wafer placement surface, the reference surface being not provided with the small projections, and the microholes may have a length of 0.01 mm or more and 0.5 mm or less in an up-down direction. In this manner, the height of the space between the rear surface of the wafer and the upper surface of the porous plug is maintained at a low level, thus it is possible to prevent arc discharge from occurring in the space. Note that the height of a reference surface may vary by small projection. The height of a reference surface may be the same as the height of the bottom surface of a small projection closest to the first hole.

In the member for semiconductor manufacturing apparatus of the present invention, the first hole may have a first hole upper section with a small diameter, a first hole lower section with a large diameter, and a step section that forms a boundary between the first hole upper section and the first hole lower section. The insulating case may have an insulating case upper section with a small diameter to be inserted in the first hole upper section, an insulating case lower section with a large diameter to be inserted in the first hole lower section, and a shoulder section that forms a boundary between the insulating case upper section and the insulating case lower section, and is to be in contact with the step section. In this manner, the upper surface of the insulating case can be easily positioned by bringing the shoulder section of the insulating case into contact with the step section of the first hole.

In the member for semiconductor manufacturing apparatus of the present invention, the microholes may have a diameter of 0.1 mm or more and 0.5 mm or less, and the bottom of the insulating case may be provided with the microholes that are 10 or more in number. In this setting, the gas supplied to the second hole smoothly flows to the rear surface of the wafer.

In the member for semiconductor manufacturing apparatus of the present invention, a lower surface of the porous plug may be located at or below (preferably, below the upper surface of the conductive substrate) the upper surface of the conductive substrate. If the lower surface of the porous plug is located higher than the upper surface of a metal joining layer, arc discharge occurs between the lower surface of the porous plug and the conductive substrate. In contrast, when the lower surface of the porous plug is located at or below the upper surface of a metal joining layer, such an arc discharge can be prevented.

In the member for semiconductor manufacturing apparatus of the present invention, the insulating case may be formed by integrating an upper member and a lower member, a length of the upper member in an up-down direction may be shorter than a length of the ceramic plate in an up-down direction, and the lower surface of the porous plug may be located at or above a lower surface of the upper member. In this manner, when the member for semiconductor manufacturing apparatus is manufactured, the porous plug having a short length is inserted into the bottomed hole of the upper member having a short length, and subsequently, the upper member and the lower member can be integrated. In this manner, the insertion distance of the porous plug is reduced, thus the porous plug is unlikely to be deformed.

### BRIEF DESCRIPTION OF THE DRAWINGS

FIG. 1 is a vertical cross-sectional view of a member 10 for semiconductor manufacturing apparatus.

FIG. 2 is a plan view of a ceramic plate 20.

FIG. 3 is a partially enlarged view of FIG. 1.

FIGS. 4A to 4D are manufacturing process diagrams of an integral member As1.

FIGS. 5A to 5C are manufacturing process diagrams of the member 10 for semiconductor manufacturing apparatus.

FIG. 6 is a partially enlarged view illustrating an integral member As2 and its periphery.

### DETAILED DESCRIPTION OF THE INVENTION

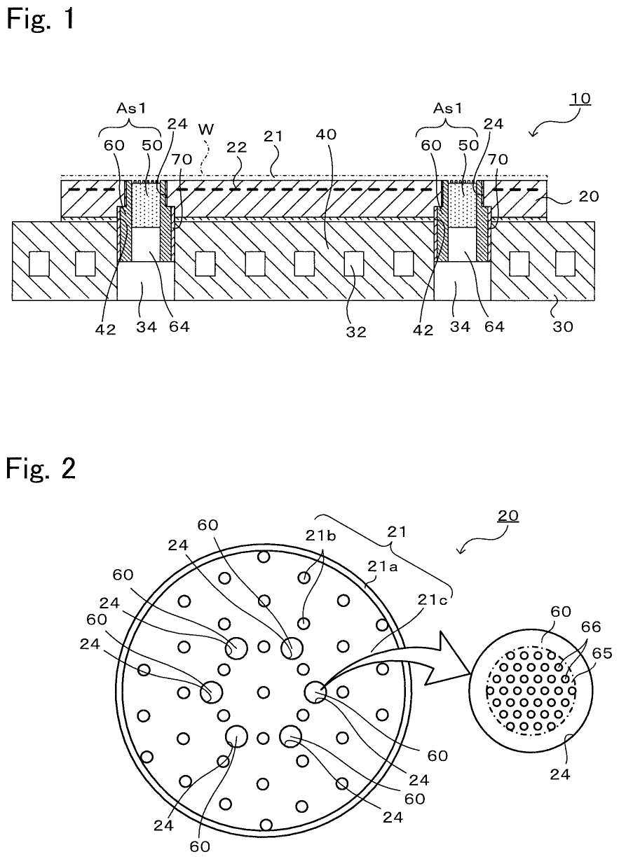

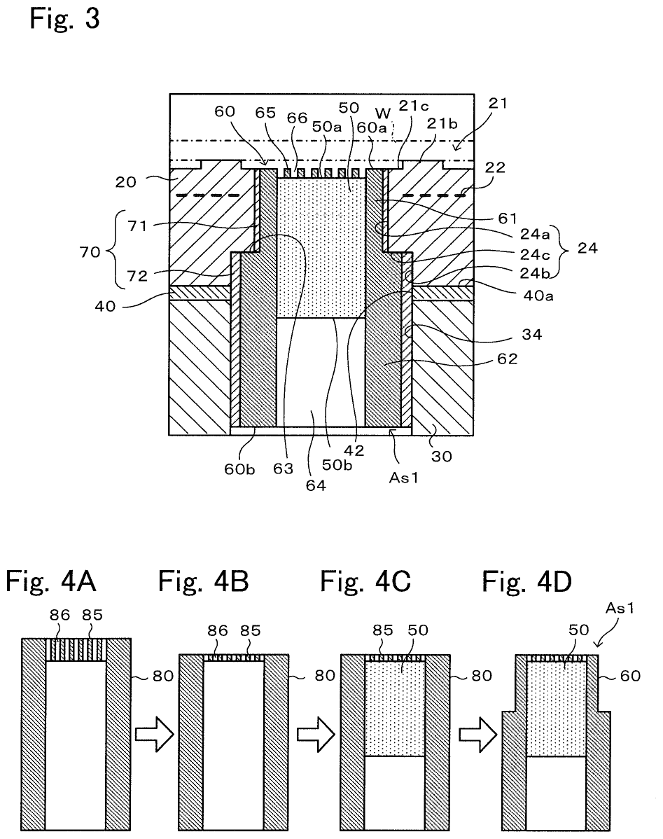

Next, a preferred embodiment of the present invention will be described with reference to the drawings. FIG. 1 is a vertical cross-sectional view of a member 10 for semiconductor manufacturing apparatus, FIG. 2 is a plan view of a ceramic plate 20, and FIG. 3 is a partially enlarged view of FIG. 1.

The member 10 for semiconductor manufacturing apparatus includes a ceramic plate 20, a cooling plate 30, a metal joining layer 40, a porous plug 50, and an insulating case 60.

The ceramic plate 20 is a ceramic circular plate (for example, a diameter of 300 mm, a thickness of 5 mm) such as an alumina sintered body and an aluminum nitride sintered body. The upper surface of the ceramic plate 20 is a wafer placement surface 21. An electrode 22 is embedded in the ceramic plate 20. As illustrated in FIG. 2, on the wafer placement surface 21 of the ceramic plate 20, a seal band 21a is formed along the outer edge, and a plurality of small circular projections 21b are formed on the entire surface. The seal band 21a and the small circular projections 21b have the same height, which is several μm to several tens μm. The electrode 22 is a planar mesh electrode that is used as an electrostatic electrode, and a DC voltage can be applied thereto. When a DC voltage is applied to the electrode 22, a wafer W is absorbed and fixed to the wafer placement surface 21 (specifically, the upper surface of the seal band 21a and the upper surfaces of the small circular projections 21b) by an electrostatic adsorption force, and when application of the DC voltage is released, the adsorption and fixation of the wafer W to the wafer placement surface 21 is released. Note that the area of the wafer placement surface 21, which is not provided with the seal band 21a and the small circular projections 21b, is referred to as a reference surface 21c.

The ceramic plate 20 is provided with a first hole 24. The first hole 24 is a through-hole that penetrates the ceramic plate 20 and the electrode 22 in an up-down direction. As illustrated in FIG. 3, the first hole 24 is a hole with a step. A first hole upper section 24a is thin, and a first hole lower section 24b is thick. The first hole 24 is a hole in which the first hole upper section 24a in a cylindrical shape with a small diameter and the first hole lower section 24b in a cylindrical shape with a large diameter are continuous, and has a step section 24c at the boundary between the first hole upper section 24a and the first hole lower section 24b. Multiple sections (for example, multiple sections provided at regular intervals in a circumferential direction) of the ceramic plate 20 are each provided with the first hole 24.

The cooling plate 30 is a circular plate (circular plate with a diameter equal to or larger than the diameter of the ceramic plate 20) having a favorable thermal conductivity. A refrigerant flow path 32 through which a refrigerant circulates and a gas hole 34 for supplying a gas to the porous plug 50 are formed inside the cooling plate 30. The refrigerant flow path 32 is formed in the entirety of the cooling plate 30 in a plan view from an entrance to an exit in a one-stroke pattern. The gas hole 34 is a hole in a cylindrical shape, and is provided coaxially with the first hole 24 so as to communicate therewith. The diameter of the gas hole 34 is approximately the same as the diameter of the first hole lower section 24b. The material for the cooling plate 30 includes, for example, a metal material and a metal matrix composite (MMC). The metal material includes Al, Ti, Mo or an alloy of these. The MMC includes a material containing Si, SiC and Ti (also referred to as SiSiCTi) and a material obtained by impregnating a SiC porous body with Al and/or Si. As the material for the cooling plate 30, it is preferable to select a material with a thermal expansion coefficient closer to that of the material for the ceramic plate 20. The cooling plate 30 is also used as an RF electrode. Specifically, an upper electrode (not illustrated) is disposed above the wafer placement surface 21, and when high-frequency power is applied to parallel plate electrodes comprised of the upper electrode and the cooling plate 30, a plasma is generated.

The metal joining layer 40 joins the lower surface of the ceramic plate 20 to the upper surface of the cooling plate 30. The metal joining layer 40 is formed, for example, by thermal compression bonding (TCB). TCB is a publicly known method in which a metal joining material is inserted between two members to be joined, and the two members are pressure-bonded with heated at a temperature lower than or equal to the solidus temperature of the metal joining material. The metal joining layer 40 is provided with a through-hole 42 penetrating in an up-down direction so as to communicate with the first hole 24 of the ceramic plate 20 and the gas hole 34 of the cooling plate 30. The diameter of the through-hole 42 is the same as the diameter of the gas hole 34. The metal joining layer 40 and the cooling plate 30 of this embodiment correspond to the conductive substrate of the present invention, and the through-hole 42 and the gas hole 34 of this embodiment correspond to the second hole of the present invention.

The porous plug 50 is a porous cylindrical member that allows a gas to flow in an up-down direction. The porous plug 50 is composed of an electrically insulating material such as alumina. An upper surface 50a of the porous plug 50 is in contact with a bottom 65 of the insulating case 60. A lower surface 50b of the porous plug 50 is located at or below an upper surface 40a of the metal joining layer 40, and above a lower surface 60b of the insulating case 60.

The insulating case 60 is a cup-shaped member composed of dense ceramic (such as dense alumina). The insulating case 60 has a bottomed hole 64 opened in its lower surface. The outer peripheral surface of the insulating case 60 is bonded and fixed to the inner peripheral surfaces of the first hole 24, the through-hole 42 and the gas hole 34 by an adhesive layer 70 from the upper surface of the first hole 24 to the inside of the gas hole 34. The inner diameter of the bottomed hole 64 is constant. The outer diameter of an insulating case upper section 61 is thin, and the outer diameter of an insulating case lower section 62 is thick. The boundary between the insulating case upper section 61 and the insulating case lower section 62 is a shoulder section 63. The outer peripheral surface of the insulating case upper section 61 is bonded and fixed to the inner peripheral surface of the first hole upper section 24a of the first hole 24 via an upper adhesive layer 71. The outer peripheral surface of the insulating case lower section 62 is bonded and fixed to the inner peripheral surface of the first hole lower section 24b, and the inner peripheral surfaces of the through-hole 42 of the metal joining layer 40 and the gas hole 34 of the cooling plate 30 via a lower adhesive layer 72. It is designed that when the shoulder section 63 of the insulating case 60 is brought into contact with the step section 24c of the first hole 24, an upper surface 60a of the insulating case 60 is at the same height as a reference surface 21c of the wafer placement surface 21. Note that “the same” includes a case of substantially the same (for example, a case of within a range of tolerance) in addition to a case of completely the same (the same is applied below). The lower surface 60b of the insulating case 60 is located inside the gas hole 34. The insulating case 60 has a plurality of microholes 66. The microholes 66 are provided to penetrate the bottom 65 of the bottomed hole 64 of the insulating case 60 in an up-down direction. The length of the microholes 66 in an up-down direction is preferably, 0.01 mm or more and 0.5 mm or less, more preferably, 0.05 mm or more and 0.2 mm or less, and particularly preferably, 0.05 mm or more and 0.1 mm or less in a device in which a high voltage is applied. The diameter of the microholes 66 is preferably, 0.1 mm or more and 0.5 mm or less, and more preferably, 0.1 mm or more and 0.2 mm or less. The bottom 65 is preferably provided with the microholes 66 that are 10 or more in number.

The insulating case 60 and the porous plug 50 are integrated to form an integral member As1. The integral member As1 is obtained by inserting the porous plug 50 into the bottomed hole 64 of the insulating case 60, and bonding the outer peripheral surface of the porous plug 50 to the inner peripheral surface of the bottomed hole 64 by a bonding adhesive with the upper surface 50a of the porous plug 50 in contact with the bottom 65.

Next, an example of use of thus configured member 10 for semiconductor manufacturing apparatus will be described. First, a wafer W is placed on the wafer placement surface 21 with the member 10 for semiconductor manufacturing apparatus installed in a chamber which is not illustrated. The pressure in the chamber is then reduced and adjusted by a vacuum pump to achieve a predetermined degree of vacuum, and a DC voltage is applied to the electrode 22 of the ceramic plate 20 to generate an electrostatic adsorption force and cause the wafer W to be absorbed and fixed to the wafer placement surface 21 (specifically, the upper surface of the seal band 21a and the upper surfaces of the small circular projections 21b). Next, a reactive gas atmosphere with a predetermined pressure (for example, several 10 s to several 100 s of Pa) is formed in the chamber, and in this state, a high-frequency voltage is applied across an upper electrode (not illustrated) provided in a ceiling portion in the chamber and the cooling plate 30 of the member 10 for semiconductor manufacturing apparatus to generate a plasma. The surface of the wafer W is processed by the generated plasma. A refrigerant is circulated through the refrigerant flow path 32 of the cooling plate 30. A back side gas is introduced into the gas hole 34 from a gas cylinder which is not illustrated. A heat transfer gas (for example, helium) is used as the back side gas. The back side gas is supplied and enclosed in the space between the rear surface of the wafer W and the reference surface 21c of the wafer placement surface 21 through the gas hole 34 of the cooling plate 30, the bottomed hole 64 of the insulating case 60, the porous plug 50 and the plurality of microholes 66. Heat is efficiently transferred between the wafer W and the ceramic plate 20 due to the presence of the back side gas.

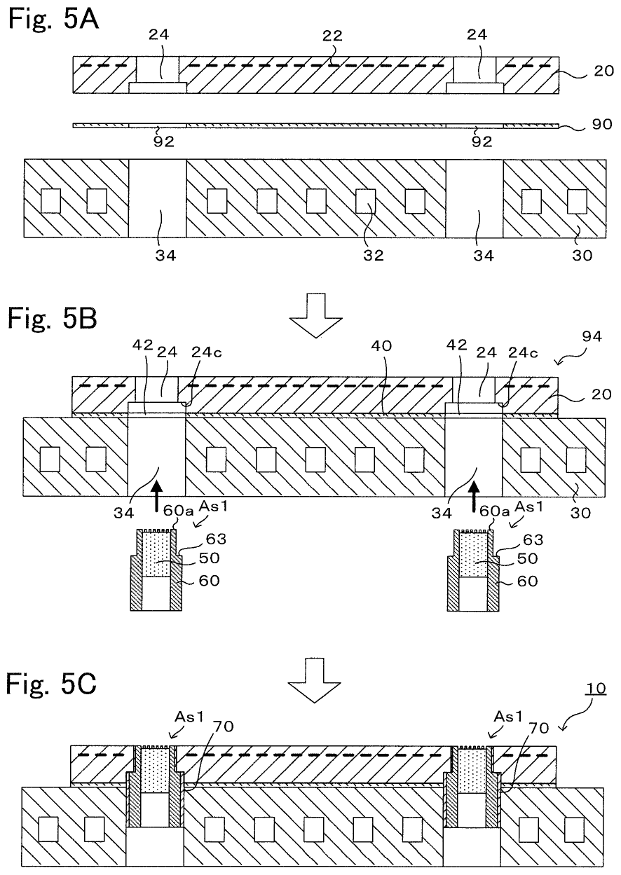

Next, a manufacturing example of the member 10 for semiconductor manufacturing apparatus will be described with reference to FIGS. 4A to 4D and 5A to 5C. FIGS. 4A to 4D are manufacturing process diagrams of the integral member As1, and FIGS. 5A to 5C are manufacturing process diagrams of the member 10 for semiconductor manufacturing apparatus. First, a plurality of through-holes 86 are formed in a bottom 85 of a thick-bottom insulating cup 80 by laser machining (FIG. 4A). The diameter of the through-holes 86 is the same as the diameter of the microholes 66. Subsequently, the insulating cup 80 is cut so that the thickness of the bottom 85 of the thick-bottom insulating cup 80 is reduced to the thickness of the bottom 65 of the insulating case 60 (FIG. 4B). Thus, the length of the through-holes 86 in an up-down direction can be adjusted to 0.05 mm or more and 0.2 mm or less. Consequently, the through-holes 86 become the microholes 66. Subsequently, a bonding adhesive is applied to the inner peripheral surface of the bottomed hole of the insulating cup 80, and a separately prepared porous plug 50 is inserted into the bottomed hole to come into contact with the bottom 85, and is bonded thereto (FIG. 4C). Finally, the insulating cup 80 is cut so that the outer shape of the insulating cup 80 becomes the outer shape of the insulating case 60, thus the integral member As1 is obtained in which the insulating case 60 and the porous plug 50 are integrated (FIG. 4D). Note that the through-holes 86 may be formed by laser machining after the insulating cup 80 is cut so that the thickness of the bottom 85 of the insulating cup 80 is reduced to the thickness of the bottom 65 of the insulating case 60.

Aside from this, the ceramic plate 20, the cooling plate 30 and the metal joining material 90 are prepared (FIG. 5A). The ceramic plate 20 has the embedded electrode 22, and includes the first hole 24. The cooling plate 30 has the embedded refrigerant flow path 32, and includes the gas hole 34. In the metal joining material 90, a preparation hole 92 is formed in advance at a position corresponding to the through-hole 42.

The lower surface of the ceramic plate 20 and the upper surface of the cooling plate 30 are joined by TCB to obtain a joined body 94 (FIG. 5B). TCB is performed, for example, as follows. First, the metal joining material 90 is inserted between the lower surface of the ceramic plate 20 and the upper surface of the cooling plate 30 to form a layered body. In this process, the first hole 24 of the ceramic plate 20, the preparation hole 92 of the metal joining material 90, and the gas hole 34 of the cooling plate 30 are coaxially stacked. The layered body is pressurized at a temperature (for example, a temperature in a range from the solidus temperature minus 20° C. to the solidus temperature) lower than or equal to the solidus temperature of the metal joining material 90 to be joined, then is placed at a room temperature. Thus, the metal joining material 90 becomes the metal joining layer 40, the preparation hole 92 becomes the through-hole 42, and the joined body 94 is obtained in which the ceramic plate 20 and the cooling plate 30 are joined by the metal joining layer 40. As the metal joining material, an Al—Mg based joining material and an Al—Si—Mg based joining material may be used. For example, when TCB is performed using an Al—Si—Mg based joining material, the layered body is pressurized in a heated state in a vacuum atmosphere. A metal joining material 90 with a thickness of approximately 100 μm is preferably used.

Subsequently, a bonding adhesive is applied to part of the inner peripheral surface of the first hole 24 of the ceramic plate 20, the inner peripheral surface of the through-hole 42 of the metal joining layer 40, and the inner peripheral surface of the gas hole 34 of the cooling plate 30. The first hole 24, the through-hole 42 and the gas hole 34 are then vacuumed with an upper opening of the first hole 24 closed, removing air bubbles from the bonding adhesive, and the integral member As1 is inserted into these holes 34, 42, 24. It is designed that when the shoulder section 63 of the insulating case 60 of the integral member As1 is brought into contact with the step section 24c of the first hole 24, the upper surface 60a of the insulating case 60 is flush with the reference surface 21c (see FIG. 3) of the wafer placement surface 21. Subsequently, the bonding adhesive is hardened to form the adhesive layer 70, and the member 10 for semiconductor manufacturing apparatus is obtained (FIG. 5C).

In the member 10 for semiconductor manufacturing apparatus described in detail above, the bottom 65 of the bottomed hole 64 of the insulating case 60, which is a separate body from the ceramic plate 20, is provided with the plurality of microholes 66. Therefore, the machinability of the microholes 66 is improved, as compared to when the ceramic plate 20 is directly provided with a plurality of microholes.

Also, the upper surface 60a of the insulating case 60 is at the same height as the reference surface 21c where the small circular projections 21b are not provided on the wafer placement surface 21, and the length of the microholes 66 in an up-down direction is preferably 0.05 mm or more and 0.2 mm or less. When the length is 0.05 mm or more, favorable machinability is likely to be secured. When the length is 0.2 mm or less, the height of the space between the rear surface of the wafer W and the upper surface 50a of the porous plug 50 is maintained at a low level, thus it is possible to prevent arc discharge from occurring in the space. Incidentally, when the height of the space is high, arc discharge occurs when electrons generated due to ionization of helium are accelerated to collide with other helium. However, when the height of the space is low, such an arc discharge is prevented.

Furthermore, the first hole 24 has the first hole upper section 24a with a small diameter, the first hole lower section 24b with a large diameter, and the step section 24c that forms the boundary between the first hole upper section 24a and the first hole lower section 24b. The insulating case 60 has the insulating case upper section 61 with a small diameter to be inserted into the first hole upper section 24a, the insulating case lower section 62 with a large diameter to be inserted into the first hole lower section 24b, and the shoulder section 63 to be brought into contact with the step section 24c that forms the boundary between the insulating case upper section 61 and the insulating case lower section 62. Thus, the upper surface 60a of the insulating case 60 can be easily positioned by bringing the shoulder section 63 of the insulating case 60 into contact with the step section 24c of the first hole 24.

Still furthermore, the diameter of the microholes 66 is preferably 0.1 mm or more and 0.5 mm or less, and the bottom 65 of the insulating case 60 is preferably provided with the microholes 66 that are 10 or more in number. In this setting, the back side gas supplied to the gas hole 34 smoothly flows to the rear surface of the wafer W.

The lower surface 50b of the porous plug 50 is located at or below (in this case, below the upper surface 40a of the metal joining layer 40) the upper surface 40a of the metal joining layer 40. If the lower surface 50b of the porous plug 50 is located above the upper surface 40a of the metal joining layer 40, an arc discharge occurs between the lower surface 50b of the porous plug 50 and the conductive substrate (the metal joining layer 40 and the cooling plate 30). In contrast, when the lower surface 50b of the porous plug 50 is located at or below the upper surface 40a of the metal joining layer 40, such an arc discharge can be prevented.

In addition, since the upper surface 50a of the porous plug 50 is covered by the bottom 65 of the insulating case 60 provided with the microholes 66, occurrence of particles from the porous plug 50 can be prevented.

Furthermore, the lower surface 60b of the insulating case 60 is located below the lower surface 50b of the porous plug 50. Therefore, the creepage distance from the wafer W to the cooling plate 30 is increased, thus spark discharge in the porous plug 50 can be prevented. Particularly, the lower surface 60b of the insulating case 60 is located inside the gas hole 34, thus a spark discharge is likely to be prevented.

The present invention is not limited whatsoever to the above embodiment, and various embodiments are possible so long as they belong within the technical scope of the present invention.

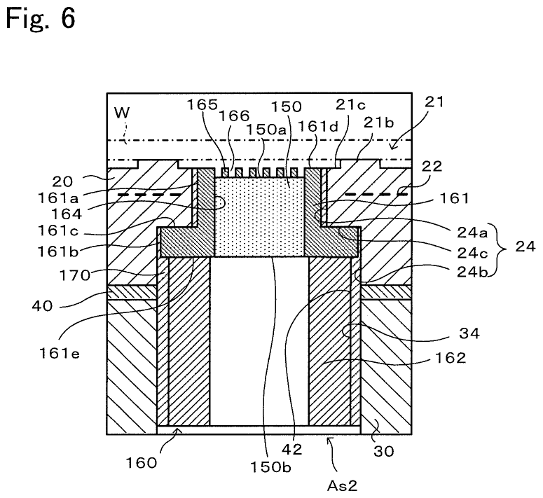

In the above embodiment, an integral member As2 illustrated in FIG. 6 may be used instead of the integral member As1. In FIG. 6, the same components as in the above embodiment are labeled with the same symbols. The integral member As2 is obtained by integrating an insulating case 160 and a porous plug 150, and is bonded and fixed via an adhesive layer 170 to the inner peripheral surfaces of the first hole 24 of the ceramic plate 20, the through-hole 42 of the metal joining layer 40 and the gas hole 34 of the cooling plate 30. The insulating case 160 is obtained by integrating an upper member 161 and a lower member 162. The upper member 161 is a cup-shaped member composed of dense ceramic (such as dense alumina). The upper member 161 has a bottomed hole 164 opened in its lower surface. The inner diameter of the bottomed hole 164 is constant. The outer diameter of an upper section 161a of the upper member 161 is thin, and the outer diameter of a lower section 161b is thick. The boundary between the upper section 161a and the lower section 161b of the upper member 161 forms a shoulder section 161c. It is designed that when the shoulder section 161c of the upper member 161 is brought into contact with the step section 24c of the first hole 24, an upper surface 161d of the upper member 161 is at the same height as the reference surface 21c of the wafer placement surface 21. The porous plug 150 is bonded and fixed to the bottomed hole 164 of the upper member 161. The porous plug 150 is a porous cylindrical member that allows a gas to flow in an up-down direction. An upper surface 150a of the porous plug 150 is in contact with a bottom 165 of the bottomed hole 164, and a lower surface 150b of the porous plug 150 is located at or above a lower surface 161e of the upper member 161. The upper member 161 has a plurality of microholes 166. The microholes 166 are provided to penetrate the bottom 165 of the bottomed hole 164 of the upper member 161 in an up-down direction. The numerical value range of the vertical length, the diameter, and the number of the microholes 166 is the same as that of the microholes 66 in the above embodiment. The lower surface 161e of the upper member 161 is integrated with an upper surface of the lower member 162 by a resin adhesive layer or a metal joining layer. The lower member 162 is a pipe composed of dense ceramic (such as dense alumina). The outer diameter of the lower member 162 is the same as or slightly smaller than the outer diameter of the lower section 161b of the upper member 161, and the inner diameter of the lower member 162 is the same as or slightly larger than the inner diameter of the bottomed hole 164 of the upper member 161. With the configuration of FIG. 6, as in the above embodiment, the machinability of the microholes 166 is improved. In addition, when the member for semiconductor manufacturing apparatus is manufactured, the porous plug 150 with a short length is inserted into the bottomed hole 164 of the upper member 161 with a short length, and subsequently, the upper member 161 and the lower member 162 can be integrated. In this manner, the insertion distance of the porous plug 150 is reduced, thus the porous plug 150 is unlikely to be deformed.

In the above embodiment, the lower surface 50b of the porous plug 50 is located inside (in other words, below the upper surface of the cooling plate 30) the gas hole 34 of the cooling plate 30; however, the configuration is not limited thereto. For example, the lower surface 50b of the porous plug 50 may be located inside (in other words, below the upper surface of the metal joining layer 40) the through-hole 42 of the metal joining layer 40. Even in this setting, the same effect as in the above embodiment is obtained.

In the above embodiment, a resin adhesive layer may be used instead of the metal joining layer 40. In that case, the cooling plate 30 corresponds to the conductive substrate of the present invention, and the gas hole 34 corresponds to the second hole.

In the above embodiment, the insulating case 60 is comprised of a single member, but may be comprised of a plurality of members.

In the above embodiment, the porous plug 50 is bonded and fixed to the inner peripheral surface of the insulating case 60; however, the configuration is not limited thereto. For example, the inner peripheral surface of the insulating case 60 and the outer peripheral surface of the porous plug 50 may be sintered and fixed together. Specifically, at least one of both surfaces may be coated with a sintering aid to be sintered, and in that case, the components of the sintering aid may become massed together at an interface.

In the above embodiment, an electrostatic electrode is illustrated as the electrode 22 to be embedded in the ceramic plate 20; however, the configuration is not limited thereto. For example, in replacement of or in addition to the electrode 22, a heater electrode (resistance heating element) may be embedded in the ceramic plate 20.

The present application claims priority from Japanese Patent Application No. 2021-211864, filed on Dec. 27, 2021, the entire contents of which are incorporated herein by reference.

What is claimed is:

1. A member for semiconductor manufacturing apparatus, comprising:
a ceramic plate having a wafer placement surface on its upper surface;
a conductive substrate provided at a lower surface of the ceramic plate;
a first hole penetrating the ceramic plate in an up-down direction;
a second hole penetrating the conductive substrate in an up-down direction, and communicating with the first hole;
a dense insulating case that has a bottomed hole opened in a lower surface, and is disposed in the first hole and the second hole;
a plurality of microholes penetrating a bottom of the bottomed hole in an up-down direction; and
a porous plug disposed in the bottomed hole and in contact with the bottom.

2. The member for semiconductor manufacturing apparatus according to claim 1,
wherein the wafer placement surface has a large number of small projections that support a wafer,
an upper surface of the insulating case is at a same height as a reference surface of the wafer placement surface, the reference surface being not provided with the small projections, and
the microholes have a length of 0.01 mm or more and 0.5 mm or less in an up-down direction.

3. The member for semiconductor manufacturing apparatus according to claim 1,
wherein the first hole has a first hole upper section with a small diameter, a first hole lower section with a large diameter, and a step section that forms a boundary between the first hole upper section and the first hole lower section, and
the insulating case has an insulating case upper section with a small diameter to be inserted in the first hole upper section, an insulating case lower section with a large diameter to be inserted in the first hole lower section, and a shoulder section that forms a boundary between the insulating case upper section and the insulating case lower section, and is to be in contact with the step section.

4. The member for semiconductor manufacturing apparatus according to claim 1,
wherein the microholes have a diameter of 0.1 mm or more and 0.5 mm or less, and the bottom of the insulating case is provided with the microholes that are 10 or more in number.

5. The member for semiconductor manufacturing apparatus according to claim 1,
wherein a lower surface of the porous plug is located inside the second hole of the conductive substrate.

6. The member for semiconductor manufacturing apparatus according to claim 1,
wherein the insulating case is formed by integrating an upper member and a lower member,
a length of the upper member in an up-down direction is shorter than a length of the ceramic plate in an up-down direction, and
the lower surface of the porous plug is located at or above a lower surface of the upper member.
